(19) United States
(12) Patent Application Publication
(10) Pub. No.: US 2011/0244633 A1
(43) Pub. Date: Oct. 6, 2011

(54) PACKAGE ASSEMBLY FOR SEMICONDUCTOR DEVICES

(76) Inventors: Ruben P. Madrid, Talisay City (PH); Romel N. Manatad, Mandaue City (PH); Maria Clemens Y. Quinones, Cebu (PH)

(21) Appl. No.: 13/082,216

(22) Filed: Apr. 7, 2011

Related U.S. Application Data
(62) Division of application No. 12/347,799, filed on Dec. 31, 2008.

(51) Int. Cl. H01L 21/50

(52) U.S. Cl. 438/122; 257/E21.499

(57) ABSTRACT

Semiconductor packages and methods for making and using such semiconductor packages are described. The semiconductor packages contain a dual gauge heat sink exposed on an upper part of the package, a leadframe containing a gate lead and an exposed drain pad on a lower part of the package, and a semiconductor die containing an IC device located between the heat sink and the leadframe. The gate of the IC device is connected to the gate lead of the leadframe using a bond interconnect wire or a gate interconnect clip located and placed under the heat sink and in between the heat sink and main leadframe. Such a configuration provides both a simple design for the semiconductor package and a simple method of manufacturing. Other embodiments are described.

### CROSS-REFERENCE TO RELATED APPLICATION

This patent application is a divisional application of U.S. application Ser. No. 12/347,799, filed on Dec. 31, 2008, the entire disclosure of which is hereby incorporated by reference.

### FIELD

This application relates generally to semiconductor devices and methods for making such devices. More specifically, this application describes semiconductor packages and methods for making and using such semiconductor packages.

### BACKGROUND

Semiconductor packages are well known in the art. Often, these packages may include one or more semiconductor devices, such as an integrated circuit (“IC”) die or chip, which may be connected to a die pad that is centrally formed in a lead frame which contain a series of leads. In some cases, bond wires electrically connect the IC die to a series of terminals that serve as an electrical connection to an external device, such as a printed circuit board (“PCB”). An encapsulating material can be used to cover the bond wires, the IC die, the terminals, and/or other components of the semiconductor device to form the exterior of the semiconductor package. A portion of the terminals and possibly a portion of the die pad may be externally exposed from the encapsulating material. In this manner, the die may be protected from environmental hazards—such as moisture, contaminants, corrosion, and mechanical shock—while being electrically and mechanically connected to an intended device that is external to the semiconductor package.

After it has been formed, the semiconductor package is often used in an ever growing variety of electronic applications, such as disk drives, USB controllers, portable computer devices, cellular phones, and so forth. Depending on the die and the electronic application, the semiconductor package may be highly miniaturized and may need to be as small as possible.

### SUMMARY

This application relates to semiconductor packages and methods for making and using such semiconductor packages. The semiconductor packages contain a dual gauge heat sink exposed on an upper part of the package, a leadframe containing a gate lead and an exposed drain pad on a lower part of the package, and a semiconductor die containing an IC device located between the heat sink and the leadframe. The gate of the IC device is connected to the gate lead of the leadframe using a bond interconnect wire or a gate interconnect clip. Such a configuration provides both a simple design for the semiconductor package and a simple method of manufacturing.

### BRIEF DESCRIPTION OF THE DRAWINGS

The following description can be better understood in light of the Figures, in which:

FIG. 1 shows an upper view of some embodiments of the semiconductor packages;

FIG. 2 depicts a bottom view of some embodiments of the semiconductor packages;

FIGS. 3 and 4 show a top view of some embodiments of the semiconductor packages with a cut-away view showing the internal components;

FIG. 5 shows a bottom view of some embodiments of the semiconductor packages with a cut-away view showing the internal components;

FIG. 6 shows a side view of some embodiments of the semiconductor packages;

FIG. 7 shows a top view of some embodiments of the semiconductor packages with the internal components illustrated;

FIG. 8 shows a plan view of some embodiments of the semiconductor packages with the internal components separated from each other;

FIG. 9 shows some embodiments of a method for making semiconductor packages containing a leadframe ready for assembly;

FIG. 10 shows some embodiments of a method for making semiconductor packages containing a leadframe with solder paste intended for die attachment;

FIG. 11 shows some embodiments of a method for making semiconductor packages containing a leadframe with a die attached thereto;

FIG. 12 shows some embodiments of a method for making semiconductor packages containing solder paste on top of the die surface solderable area and on the leadframe source leadpost and gate lead post including the die;

FIG. 13 depicts some embodiments of a method for making semiconductor packages showing a heat sink and a gate clip ready for assembly;

FIG. 14 depicts some embodiments of a method for making semiconductor packages showing the attachment of the gate clip;

FIG. 15 shows some embodiments of a method for making semiconductor packages showing the attachments of a heat sink after the gate clip attachment;

FIG. 16 depicts some embodiments of a method for making semiconductor packages after a reflow procedure has been performed;

FIG. 17 depicts some embodiments of a method for making semiconductor packages showing a film assist molding procedure;

FIG. 18a depicts some embodiments of a method for making semiconductor packages showing a plating procedure after molding, which protects the leadframe and the exposed heat sink from corrosion;

FIG. 18b depicts some embodiments of a method for making semiconductor packages showing a punch singulation procedure that can be used for high volume production;

FIG. 19 depicts some embodiments of a method for making semiconductor packages showing an electrical testing procedure;

FIG. 20 depicts some embodiments of a method for making semiconductor packages showing a marking procedure;

FIG. 21 depicts a top view of other embodiments of the semiconductor packages with a cut-away view showing the internal components;

FIG. 22 shows a side view of gate wired embodiments of the semiconductor packages; and

FIG. 23 shows a top view of gate wired embodiments of the semiconductor packages with the internal components illustrated.

The Figures illustrate specific aspects of the semiconductor packages and methods for making such devices. Together with the following description, the Figures demonstrate and explain the principles of the methods and structures produced through these methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor packages and associated methods of using the packages can be implemented and used without employing these specific details. Indeed, the semiconductor packages and associated methods can be placed into practice by modifying the illustrated devices and methods and can be used in conjunction with any other apparatus and techniques conventionally used in the industry. For example, while the description below focuses on methods for making semiconductor packages in the IC industry, it could be used for packaging for other electronic devices like optoelectronic devices, solar cells, MEMS structures, lighting controls, power supplies, and amplifiers.

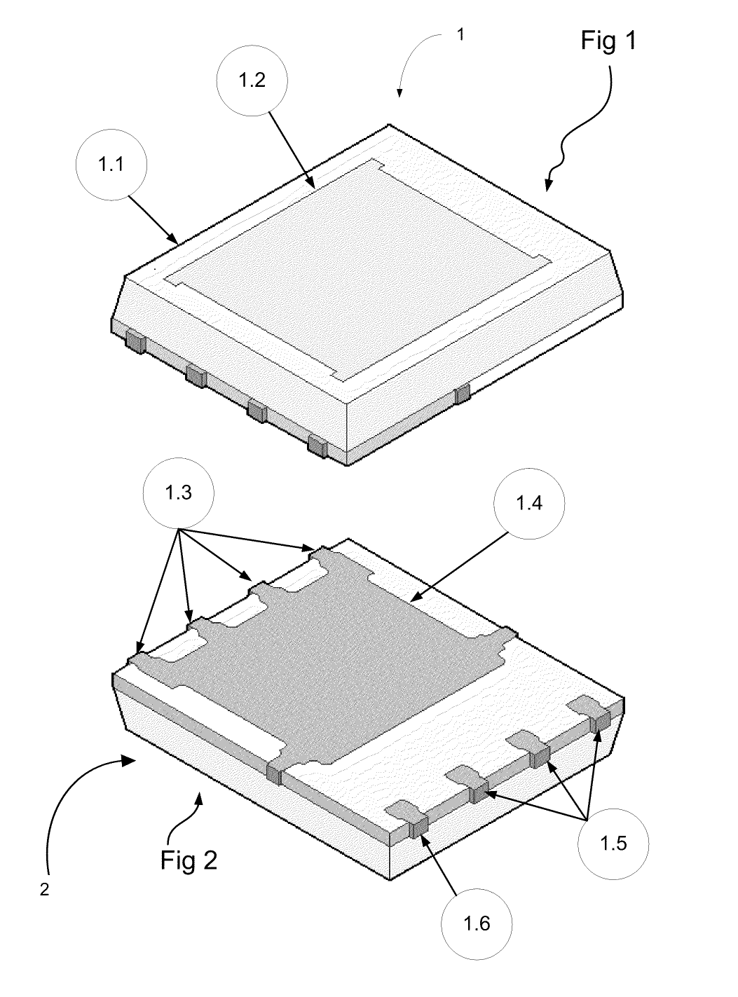

FIGS. 1-20 shows some embodiments of semiconductor packages and the methods for manufacturing such packages. FIG. 1 depicts a top view of a molded semiconductor package 1 containing a molding material 1.1 and a fully exposed heat sink 1.2. As shown in FIG. 1, substantially all of the upper surface of the heat sink is not encapsulated and is over the surface of molding material 1.1 and therefore remains exposed over the top package surface. The heat sink operates to absorb significant amounts of heat from the inside of the semiconductor package, thereby allowing efficient operation of the devices, maintaining the constant cooing of semiconductor device therein, and reducing or preventing any damage from heating. Accordingly, the heat sink can be configured with a size and shape that will maximize the amount of heat conducted. In some embodiments, the heat sink can be made of any material that will be a good thermal conductor, including copper, copper alloys, aluminum, alloy 42, or combinations thereof. In other embodiments, the heat sink can be made of any dual gauge material such as copper, cu alloys, aluminum, or combinations thereof.

As shown in FIGS. 1-2, the semiconductor package is partially encapsulated in a molding material 1.1. The molding material 1.1 used in these embodiments can comprise any molding material known in the art that flows well and therefore minimizes the formation of any gaps. The molding material can be any material known in the art, including an epoxy molding compound, a thermoset resin, a thermoplastic material, or potting material. In some aspects, the molding material comprises an epoxy molding compound such as an epoxy material with a low thermal expansion (a low CTE), fine filler size (for good flow distribution of the molding material), and high adhesion strength.

FIG. 2 shows a bottom view of a molded semiconductor package 2 containing drain leads 1.3, a drain pad 1.4, source leads 1.5, and gate lead 1.6. The leads serve as terminals for the semiconductor package 2 and are used to connect the package 2 to an external device, such as printed circuit board (PCB) or in package-in-package assembly into one package with the combination of multiple package. When combined with this external device, the semiconductor package can be part of an electrical system. The leads and the drain pad are all part of the leadframe (or main leadframe).

The leadframe supports the die, serves as part of the I/O interconnection system, and also provides a thermally conductive path for dissipating some of the heat generated by the die. The leadframe may have any component or characteristic that allows the die to be electrically connected to the PCB. The material of the leadframe can comprise any conductive metal or metal alloy known in the art, including Cu, alloy 42, aluminum, or combinations thereof. In some embodiments, the leadframe comprises high pin count and low pin count. In some instances, the leadframe can contain a layer of metal plating (not shown), if desired. For example, the leadframe may be electroplated or otherwise coated with a layer of a solderable conductive material, such as tin, gold, lead, silver, Ni—Pd, Ni—Pd—Au, Ni—Pd—Au/Ag, and/or another solderable material.

In some embodiments, the leadframe can have one or more recesses that define a die pad (or die attach pad). For instance, an upper surface of the leadframe may contain a recess that is sized and shaped to allow a semiconductor die to be disposed and attached thereon. In other embodiments, the leadframe may also contain tie bars as are commonly known in the art. The semiconductor package may have any number of tie bars.

The lead frame contains a plurality of leads disposed about the perimeter of the lead frame. The semiconductor package may have any desired number of leads with any desired characteristic. In some embodiments, FIGS. 1-2 illustrates that the semiconductor package may have eight leads (e.g., 3 source leads, 4 drain leads, and a gate lead). Nevertheless, one of skill in the art will understand that the semiconductor package may comprise more or less leads than eight. Additionally, one of skill in the art will recognize that the semiconductor package may comprise both active and dummy leads, where active leads are electrically connected to the die in an assembled package and dummy leads are electrically isolated from the die(s). The leads may be disposed about the perimeter of the semiconductor package in any desired manner, including those depicted in FIGS. 1-2 where the leads can be evenly spaced on the bottom edges of the package.

The leads may have any configuration that allows IC device on the semiconductor die to be electrically connected to any external device. FIGS. 1-2 illustrate those embodiments where the package comprises a gate lead that is connected to the gate of the IC device on a semiconductor die (as described herein), drain leads that are connected to the drain of the IC device, and source leads that are connected to source of the IC device. The configuration of the leads in FIGS. 1-2 can be used for electrically and/or mechanically connecting the semiconductor package to the PCB.

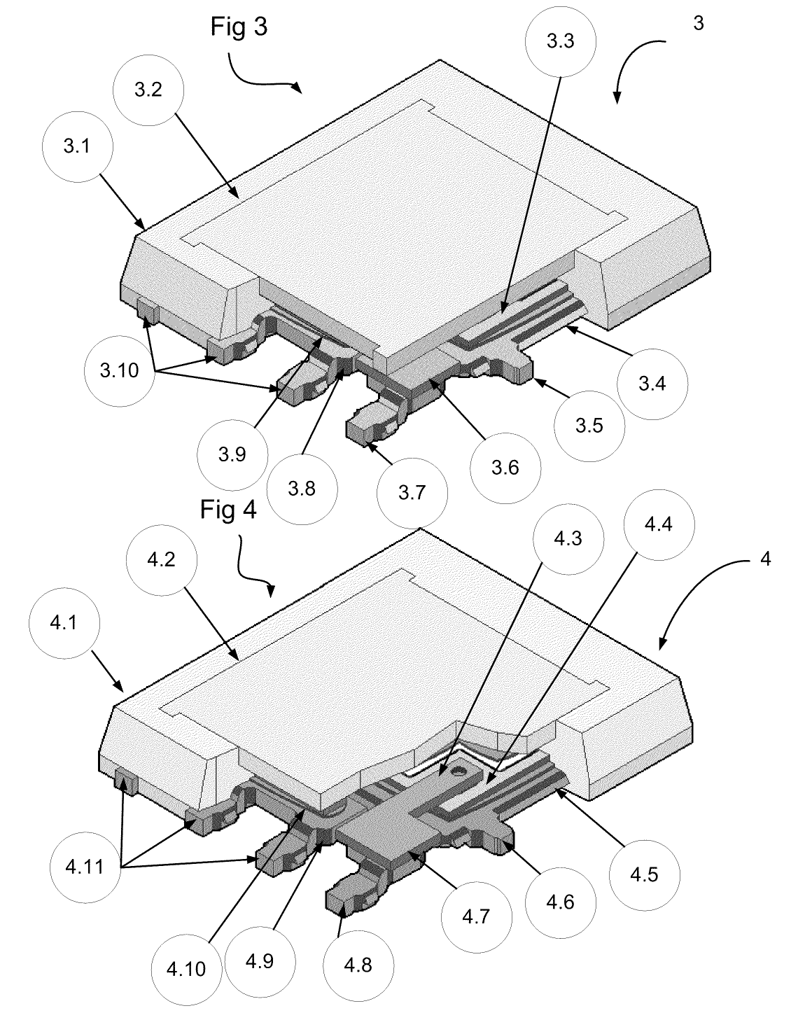

In FIG. 3, the molding material has been partially removed to show part of the internal components of a semiconductor package 3. In FIG. 3, the semiconductor package 3 contains a molding material 3.1, heat sink 3.2, a semiconductor die containing an IC device 3.3, a die attach pad 3.4 of the leadframe on which the die rests, a leadframe containing a tie bar 3.5, a gate interconnect clip 3.6 under cover by heatsink 3.2 which is sandwiched in-between the leadframe with die and the top heat sink, a gate lead 3.7, source bond pad 3.8, heat sink source pad 3.9, and the source leads 3.10.

The semiconductor die (or die) in the semiconductor package contains any IC device and may be any semiconductor die known in the art. For example, the die may be made of any known semiconductor material. Some non-limiting examples of semiconductor materials may include silicon, gallium arsenide, silicon carbide, gallium nitride, silicon and germanium, and combinations thereof.

The die may contain any number of known integrated circuit (IC) devices (or semiconductor devices). Some non-limiting examples of these devices includes diodes, transistors like BJT (bipolar junction transistors), metal-oxide-semiconductor field-effect transistors (MOSFET) including vertical MOSFETs with a trenched gate, insulated-gate field-effect transistors (IGFET), and other transistors known in the art. The IC device shown in the Figures comprises a MOSFET device that contains drain, source, and gate regions.

The source, drain, and gate regions (G, S, and D) are located on the upper surface of the die and may be electrically and/or mechanically attached to other components of the semiconductor package. In some embodiments, the G, S, and D regions may be connected to the corresponding regions of the leadframe through the use of any known connections, including solder bumps, a conductive epoxy bonding material, and/or solder paste. In some instances, the solder paste used may include lead/tin solder paste, silver filled epoxy, tin/silver/copper, and/or other lead free solders.

In FIG. 4, the molding material has been removed even more to show more of the internal components of a semiconductor package 4. The heat sink 4.2 was cut away to show the gate clip 4.3 in proper setting with connects to the die gate and gate pad of gate lead 4.8. The semiconductor package 1 contains the molding material 4.1, heat sink 4.2, gate interconnect clip pad 4.3, a die containing an IC device 4.4, a die attach pad 4.5 on which the die rests, a leadframe containing a tie bar 4.6, a gate interconnect 4.7, a gate lead 4.8, source bond pad 4.9, heat sink source pad 4.10, and source leads 4.11. The gate interconnect clip can comprise any conductive metal or metal alloy known in the art, including Cu, Alloy 42, Alumnum, and other high electrical and conductive materials, or combinations thereof. The conductive metal can be partially encapsulated with a molding material to leave the connection points (to the gate of the IC device and the gate lead) without any molding material. Thus, the gate interconnect clip can be shaped and configured according to the gate shape of the MOSFET and the gate pad of the leadframe, as well as distance between the gate of the MosFET and the leadframe gate pad. The gate clip interconnect 4.3 shape will also configure the height difference between the MosFET 4.4 and the Gate pad for accurate good electrical flow. The gate clip interconnect 4.3 can be of any shape as long as it connected firmly by a solder paste. The gate clip 4.3 is positioned under the heat sink 4.2. The heat sink 4.2 covers the gate clip interconnect 4.3 and is then protected by molding compound 4.1 during molding as shown in FIG. 4. This process keep the heat sink 4.2 in full size and exposure on top surface of the package, thus it performs top cooling and high thermal conductivity to keep the heat away from inside of the package.

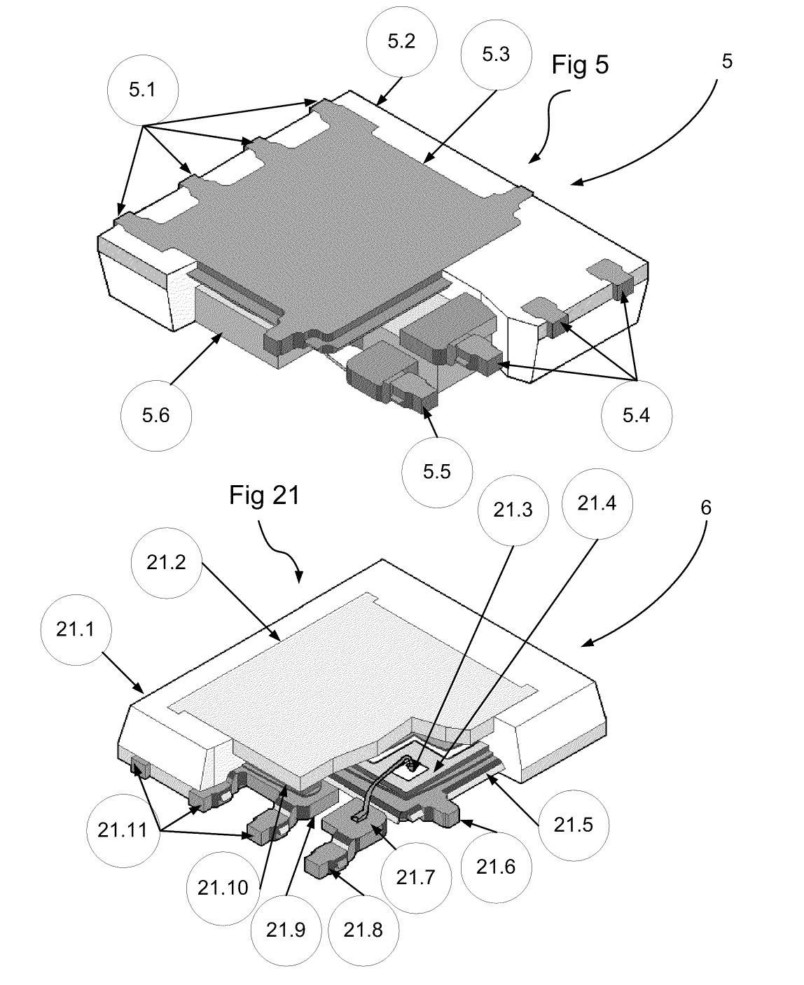

In FIG. 5, the molding material has been partially removed to show part of the internal components of a semiconductor package 5 from a bottom view. As shown, the semiconductor package contains a molding material 5.2, drain leads 5.1, drain pad 5.3, source leads 5.4, a gate lead 5.5, and a heat sink 5.6. The drain pad 5.3 is that part of the leadframe that is opposite the die attach pad and which serves as bottom cooling of the package as well as drain electrical interconnection into the printed circuit board (PCB).

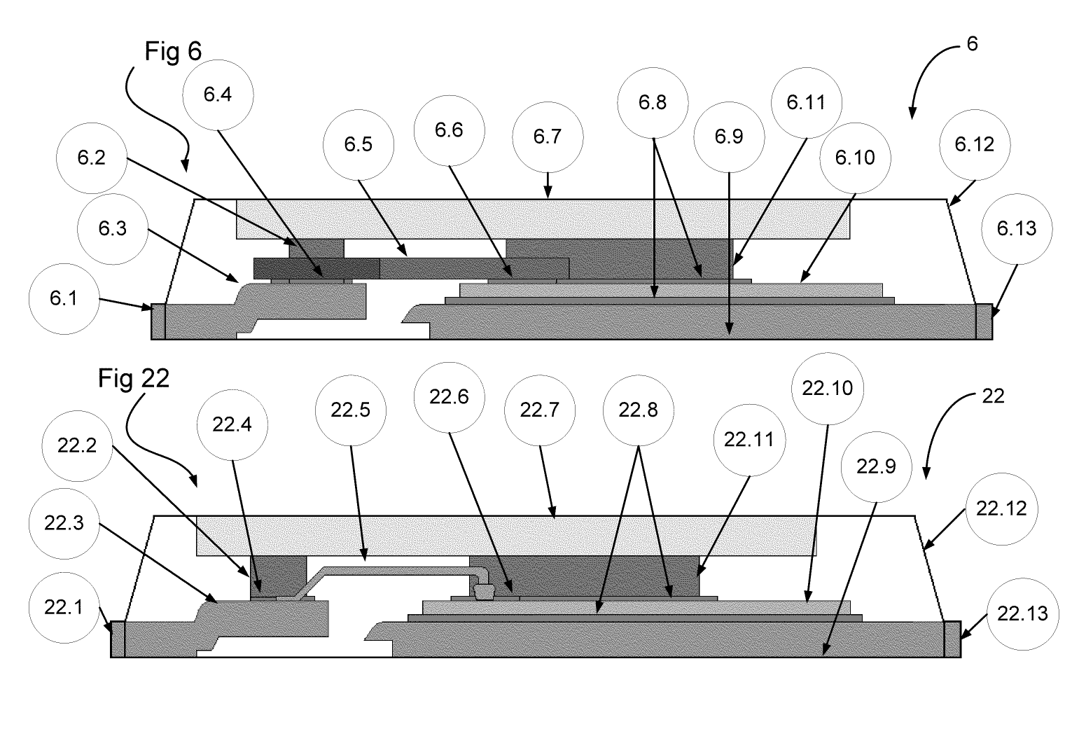

FIG. 6 shows a side view of a semiconductor package 6 that is encapsulated with molding material 6.12. The semiconductor package 6 contains gate and source leads 6.1, heat sink pad 6.2 (and 6.11), gate and source bond pad 6.3, the interface 6.4 between the gate interconnect clip 6.5 and the bond pad, the interface 6.6 between gate interconnect clip pad and the gate of the IC device, the heat sink 6.7, solder paste 6.8, drain pad 6.9, die containing MOSFET 6.10, heat sink pad 6.11, and drain leads 6.13. The heat sink source pad 6.3 is the thicker part of heat sink 6.7 that extends to touch the leadframe source pad 6.3 to form an interface connection 6.4 for source electrical flow. The heat sink source pad 6.11 is the thicker part of heat sink 6.7 that extends to touch the MosFET die 6.10 source pad with solder paste 6.8 to form an interface connection for source electrical flow. The heat sink 6.7, source pad 6.3, and heat sink pad 6.11 is located between the heat sink exposed top side and the MosFET die, as well as between the heat sink and leadframe 6.13. The heat sink source pad operates to serves as source electrical interconnection as well as heat dissipation or thermal conductive to keep the heat away from MosFET die during the operation. The heat sink can be made of high conductive metal alloy like copper, alloy 42, aluminum or a combination thereof. The clip gate interconnect 6.5 is placed in position to connect the MosFET gate interface 6.6 and connected to gate pad interface 6.4. The gate clip interconnect is located under the heat sink in parallel to heat sink source pad 6.3 and 6.11. The gate clip 6.5 is in between or is sandwiched between heat sink 6.7 and bottom leadframe 6.13 as well as the MosFET die 6.10. This method of assembly will keep the maximum size of exposed heat sink on top side of the package for efficient cooling of semiconductor device for efficient operation.

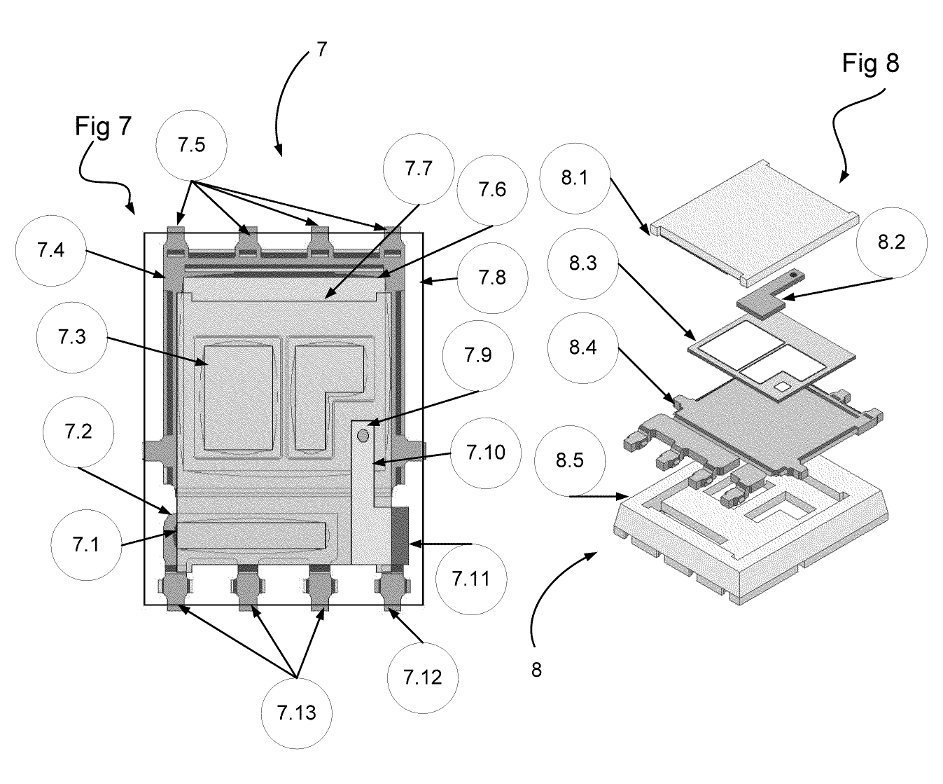

FIG. 7 shows a top assembly view of a semiconductor package 7 that is encapsulated with molding material 7.8. The semiconductor package 7 contains the source bond pad 7.2, the interface 7.3 between the source die and the heat sink, the die attach pad 7.4, drain leads 7.5, the die containing MOSFET 7.6, the heat sink 7.7, the molding material 7.8, the gate/clip interface 7.9, the gate interconnect clip 7.10, an interface 7.11 between the gate pad and the clip, gate lead 7.12, and the source lead 7.13. When used, the bond pads can be formed on the desired connection points in the package as known in the art.

FIG. 8 shows a layout view of all of these components (which are depicted in a separated configuration for clarity) in a semiconductor package 8. The semiconductor package 8 contains a heat sink 8.1, gate interconnect clip 8.2, die with an IC device (i.e., a solderable MOSFET) 8.3, a leadframe 8.4, and the molding material 8.5. FIG. 8 also illustrates how the components are arranged within the semiconductor package.

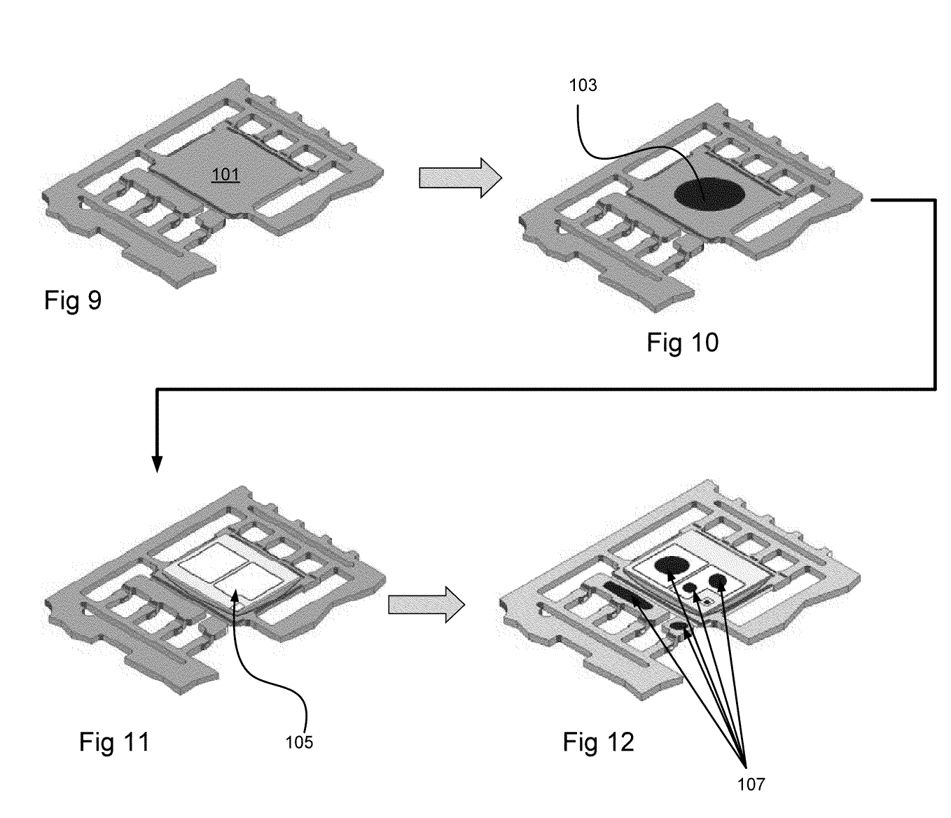

The semiconductor packages described above can be formed by any methods which form the devices illustrated in the Figures and described herein. In some embodiments, the methods begin by providing a leadframe 101, as shown in FIG. 9. The leadframe 101 can be manufactured by any known process, such as pre-formed from molten metal and shaped according to size, metal extrusion, stamping a blank sheet metal, or an etching process. In some embodiments, the leadframe 101 is made from copper, alloy 42, aluminum, other high conductive materials, or combinations thereof.

Next in the assembly process, as shown in FIG. 10, solder paste 103 is placed and provided on the die attach pad of the leadframe 101 where a die will be placed and attached. The solder paste 103 can be made of any solderable adhesive material, including Ag filled epoxy, green epoxy (SAC) SnAgCu, or combinations thereof. The solder paste 103 can be provided on the desired locations of the leadframe 101 through any process known in the art, including paste dispense writing or any screen printing process and method. In some embodiments, the solder paste 103 can be provided by syringe or in from squeegee to spread the solder paste in an entire leadframe.

Then, as shown in FIG. 11, a semiconductor die 105 is attached to the leadframe 101 die attach pad after the desired IC device (i.e., a MOSFET) has been placed and formed in the die 105 using any known semiconductor processing techniques. The die attach process affixes the die to the lead frame so that a bond is formed between the die and the metal surface of the lead frame. The die 105 can be attached to the leadframe 101 using any process, such a pick and place tool from wafer to leadframe.

Next, solder paste 107 is provided on the leadframe 101 and the die 105 as shown in FIG. 12. The solder paste 107 can be the same or different than solder paste 103. The solder paste 107 can be made of any solderable adhesive material, including Ag-filled epoxy, green epoxy, or combinations thereof. The solder paste 107 can be provided on the top of leadframe die attached pad 101 and on top of MosFET die 105 through any process known in the art, including paste dispense writing or any screen printing process.

As shown in FIG. 13, the heat sink 109 and the gate interconnect clip 111 can be made. These two components can actually be provided at this stage in the process or at any prior stage in the process. The heat sink 109 and the gate interconnect clip 111 can be provided in the same procedure or in different procedures. The heat sink can be manufactured by any process that provides the desired material with the shape and size needed. For example, when the heat sink is made of a Cu alloy metal, it can be prepared by etching or stamping the metal to the desired shape and size.

The gate interconnect clip can be manufactured by any process that provides the desired material with the shape and size needed. In some embodiments, the gate interconnect clip can be manufactured by a stamping or etching a clip from a separate leadframe, thereby creating a clip leadframe. The configuration of the clip leadframe is based on the design of the gate lead and gate of the IC device on the die 105. The clip leadframe can then be partially encapsulated with a molding material to create a pre-molded clip with exposed connection points to the gate lead and the gate of the IC device.

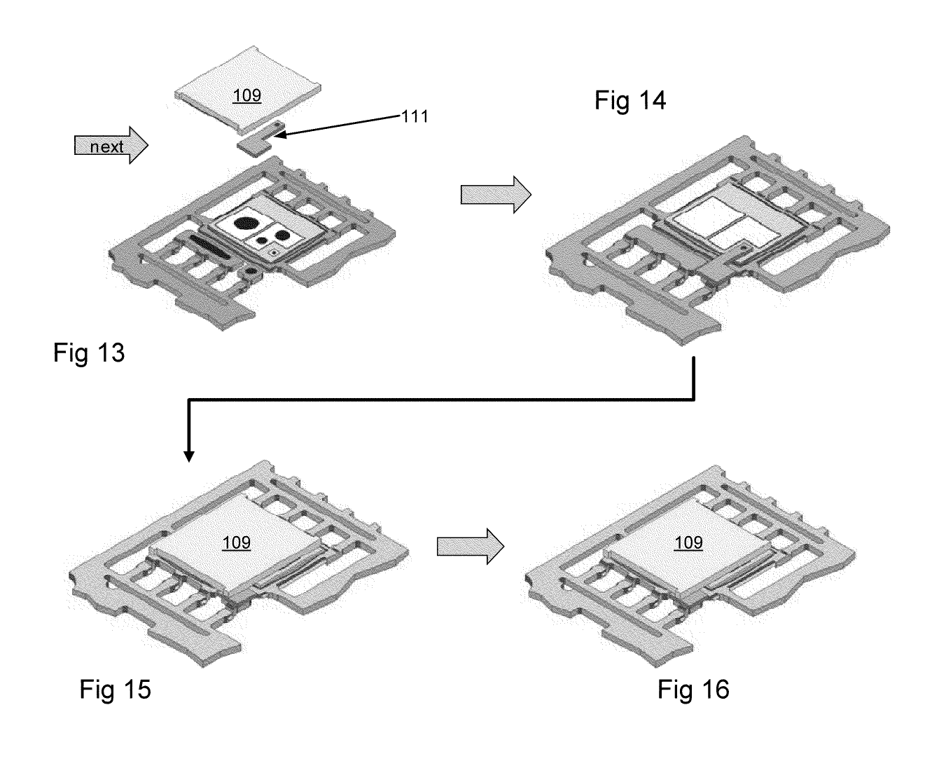

As shown in FIG. 14, the gate interconnect clip 111 is then attached to the leadframe 101 and the die 105. The gate interconnect clip 111 can be attached to the leadframe and the die using any process known in the art. In some embodiments, this attach process involves affixing the gate interconnect clip to the lead frame and the die so that a bond is formed between the gate interconnect clip and the metal surface of the leadframe and the gate of the IC device (the MOSFET).

Next, the heat sink 109 is attached to the upper surface of the die and the upper surface of leadframe source bond pad. The heat sink covers the gate interconnect clip without touching any of the surface with each part. The heat sink has a free or recess area for the gate clip NOT to touch any surface area of heat sink, as shown in FIG. 15. The heat sink 109 can be attached to the leadframe source bond pad and the die source pad area using any process known in the art. In some embodiments, this attach process involves affixing the heat sink so that the heat generated by semiconductor device will be absorbed and cool down the device during the operation.

Then, a one time reflow process is carried out on the resulting structure, as shown in FIG. 16. The reflow process heats the solder paste (both 103 and 107) and forms a better bond to the metal surfaces to which has been connected. In this process, the structure can be heated in a defined temperature profile to obtain the desired amount of reflow of the solder to cure the solder form permanent adhesion of components an assembly process. Any known reflow process can be used, including heating at a peak of about 260 to about 265 degrees Celsius for leadfree or green epoxy.

Next, the resulting device is encapsulated in a molding material 113 as shown in FIG. 17. During this encapsulation process, the upper surface of the heat sink 109 is not encapsulated and so remains exposed. The heat sink remains exposed so that the desired amount of heat can be conducted away from the IC device (the MOSFET) operating on the die. As well, the encapsulation process leaves the drain pad, the source leads, the gate lead, and the drain leads exposed so that they can be connected to the PCB. The molding material 113 may be formed to the desired shape using any encapsulation process known in the art, including a film assist molding process.

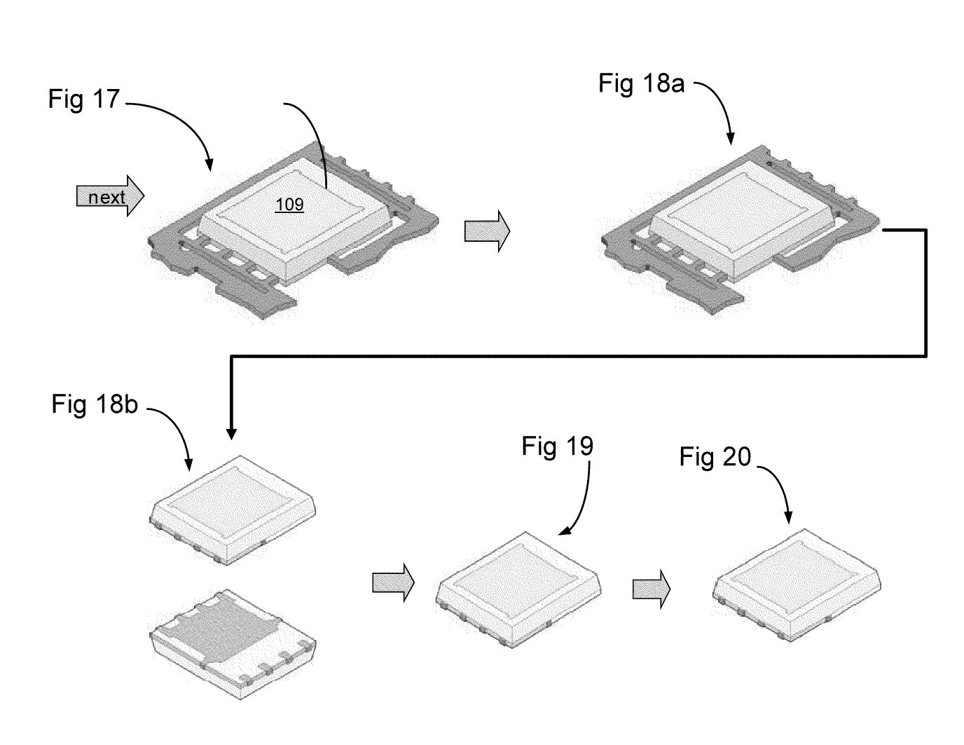

The molded semiconductor package is will undergo tin plating to cover the leadframe and exposed heat sink for good cosmetic and prevent corrosion, as shown in FIG. 18a. The tin plating process can be carried out using any process known in the art, including an automatic plating machine.

The molded and plated semiconductor package is then singulated as shown in FIG. 18b. The singulation can be carried out using any process known in the art, including a punched singulation process or a saw singulation process. Then, the singulated semiconductor packages may be electrically tested, as shown in FIG. 19. After electrical testing, the top surface the semiconductor packages may be marked according to the device code and index marked for orientation indication, as shown in FIG. 20.

In other embodiments, the semiconductor packages can be configured without the gate interconnect clip described above. In these embodiments, a wirebond can be used to connect the gate of the leadframe and the gate of the IC device. Thus, as shown in FIG. 21, the gate interconnect clip has been replaced with a gate wire interconnect 21.3.

The gate interconnect wire can also be seen in the side view of semiconductor package 22 illustrated in FIG. 22. The gate interconnect wire 22.5 connects the gate bond pad (which is located on the gate lead 22.1) and the contact pad 22.6 that is located on the gate of the MOSFET device 22.10 located on the die. In FIG. 22, the semiconductor package 22 is encapsulated with molding material 22.12. The semiconductor package 22 contains gate and source leads 22.1, heat sink pad 22.2 (and 22.11), gate and source bond pads 22.3, the gate bond pad 22.5, the heat sink 22.7, solder paste 22.8, drain pad 22.9, die containing MOSFET 22.10, and drain leads 6.13.

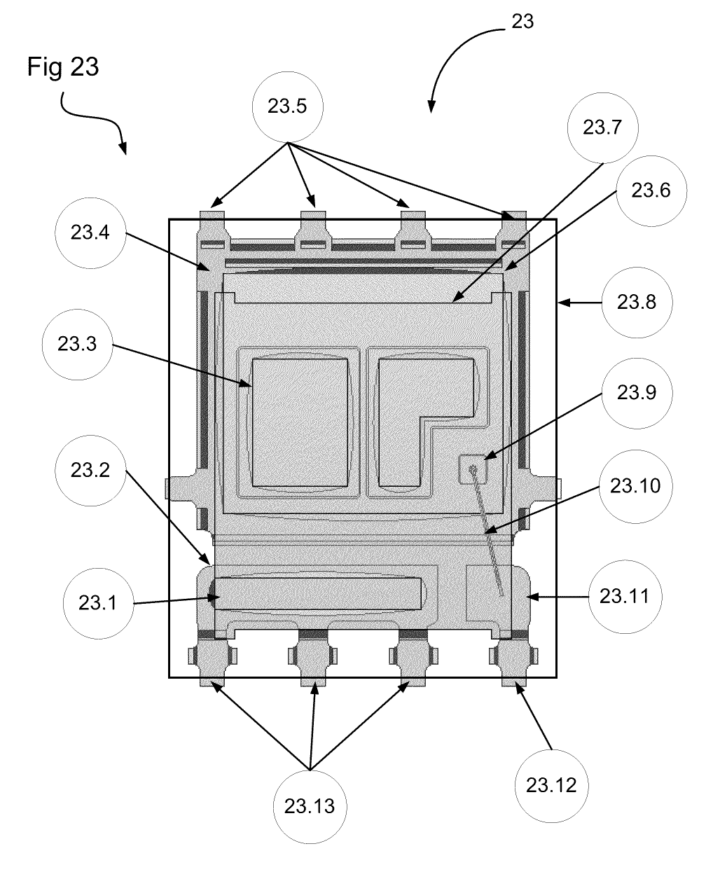

The gate interconnect wire can also be seen in the top view of semiconductor package 23 illustrated in FIG. 23. FIG. 23 shows a top view of the semiconductor package 23 that is encapsulated with molding material 23.8. The semiconductor package 23 contains the source bond pad 23.2, the interface 23.3 between the source die and the heat sink, the die attach pad 23.4, drain leads 23.5, the die containing MOSFET 23.6, the heat sink 23.7, the molding material 23.8, the bond pad 23.9 for the gate interconnect wire, the gate interconnect wire 23.10, the gate bond pad 23.11, gate lead 23.12, and the source lead 23.13.

The semiconductor packages containing the gate interconnect wire can be formed using methods similar to those described above. Instead of forming a gate interconnect clip, though, the process forms a wirebond by using any wirebonding process known in the art. As an example of the wirebonding, the die 105 can be provided with contacts pads near the exterior of the die. Wirebonds are then formed from the contact pads to the gate lead to form the electrical connection. The wirebonds can be made from any known material, including Cu, aluminum, or Au.

The semiconductor packages described above contain several features. First, they contain a sandwich gate interconnect structure that is a combination of the heat sink at the top and the leadframe at the bottom. Second, they contain a clipless MOSFET device in a single frame. Third, they can be formed in a single molding process. Fourth, the full-sized heat sink on the top of the molded package provides a high thermal dissipation and high cooling performance. Fifth, the gate interconnect clip and the gate interconnect wire are both covered by a full-sized heat sink. And sixth, they have a simple package design, a simple method of manufacture, low material cost and low CLD.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. A method of making a semiconductor package, comprising:
providing a heat sink exposed on a first surface of the package;
providing a leadframe with an exposed drain pad located on a second surface of the package opposite the first surface, the leadframe also containing an exposed gate lead, exposed drain leads, and exposed source leads;
providing a semiconductor die containing an IC device located between the heat sink and the leadframe, wherein a gate of the IC device is connected to the gate lead using a bond wire or a gate interconnect clip so that the heat sink is located over substantially all of the gate interconnect clip or substantially all of the bond wire; and
providing a molding material to encapsulate the heat sink and the leadframe except for their exposed portions.

16. The method of claim 15, wherein the heat sink comprises a dual gauge material.

17. The method of claim 15, including connecting a source of the IC device to the source lead and connecting a drain of the IC device to the drain lead via a drain pad.

18. The method of claim 15, wherein the gate interconnect clip comprises a premolded clip leadframe.

19. A method for making a semiconductor package, comprising:
providing a leadframe, the leadframe containing a die attach pad, a drain pad, and a gate lead;
providing a semiconductor die with an IC device containing a gate;
attaching the die to the die attach pad of the leadframe;
electrically connecting the gate of the IC device to the gate lead of the leadframe using a gate interconnect clip or a bondwire;
attaching a heat sink to an upper surface of the IC device so that the heat sink is located over substantially all of the gate interconnect clip or substantially all of the bond wire; and
encapsulating the resulting structure except for an upper surface of the heat sink, a lower surface of the drain pad, and an end portion of the gate lead.

20. The method of claim 19, including connecting the gate of the IC device to the gate lead by providing the gate interconnect clip and then attaching it to the gate of the IC device and to the gate lead.

21. The method of claim 20, including providing the gate interconnect clip by pre-molding a singulated clip leadframe.

22. The method of claim 19, including connecting a source of the IC device to the source lead and connecting a drain of the IC device to the drain lead via the drain pad.

23. The method of claim 19, wherein the heat sink comprises a dual gauge material.

24. The method of claim 19, wherein the dual gauge material comprises Cu, Al, Cu alloys, or combinations thereof.

25. The method of claim 21, wherein the premolding process partially encapsulates the gate interconnect clip with a first molding layer.

26. The method of claim 25, wherein the encapsulation forms a second molding layer.

27. A method for making a semiconductor package, comprising:
providing a heat sink exposed on a first surface of the package;
providing a leadframe with an exposed drain pad located on a second surface of the package opposite the first surface, the leadframe also containing an exposed gate lead, exposed drain leads, and exposed source leads;
providing a semiconductor die containing an IC device located between the heat sink and the leadframe, wherein a gate of the IC device is connected to the gate lead using a gate interconnect clip partially encapsulated with a first molding material so that a portion of the heat sink is located over the gate interconnect clip; and
providing a second molding material encapsulating the heat sink and the leadframe except for their exposed portions.

28. The method of claim 27, wherein the heat sink comprises a dual gauge material.

29. The method of claim 28, wherein the dual gauge material comprises Cu, Al, Cu alloys, or combinations thereof.

30. The method of claim 27, wherein the IC device also contains a source and a drain.

31. The method of claim 30, wherein the source of the IC device is connected to the source lead and the drain of the IC device is connected to the drain lead via a drain pad.

32. The method of claim 27, wherein the IC device comprises a MOSFET device.

33. The method of claim 27, including attaching the heat sink to the IC device so that the heat sink is located over substantially all of the gate interconnect clip.
